(19) United States
(12) Patent Application Publication
(10) Pub. No.: US 2026/0229469 A1
(43) Pub. Date: Aug. 6, 2026

(54) CONTROLLING RF POWER FOR ON-WAFER PROCESS IMPROVEMENT

(71) Applicant: ASM IP Holding B.V., Almere (NL)

(72) Inventor: Imran Ahmed Bhutta, Moorestown, NJ (US)

(21) Appl. No.: 19/461,921

(22) Filed: Jan. 28, 2026

Related U.S. Application Data
(60) Provisional application No. 63/752,187, filed on Jan. 31, 2025.

(51) Int. Cl. H01J 37/32

(52) U.S. Cl. CPC H01J 37/32926; H01J 37/32183; H01J 37/32935; H01J 37/3299

(57) ABSTRACT

According to one embodiment, a system for adjustment of RF power delivered to a plasma chamber is disclosed. One or more memory devices store correlation data. First correlation data is based on film thickness values and, for each film thickness value, a corresponding matching network value. Second correlation data is based on film thickness values and, for each film thickness value, a corresponding RF power setting. For a current wafer run, a control circuit determines a current matching network value. Using that value and the first correlation data, a current film thickness for the semiconductor wafer is determined. Using the current film thickness and the second correlation data, the corresponding RF power setting is determined. The RF power is adjusted based on the corresponding RF power setting to achieve a new film thickness that is within a desired film thickness range.

### CROSS-REFERENCE TO RELATED APPLICATIONS

This application claims priority to U.S. Provisional Patent Application Ser. No. 63/752,187 filed Jan. 31, 2025 and titled CONTROLLING RF POWER FOR ON-WAFER PROCESS IMPROVEMENT, the disclosure of which is hereby incorporated by reference in its entirety.

### BACKGROUND

The semiconductor device fabrication process uses plasma processing at different stages of fabrication to make a semiconductor devices such as microprocessors, a memory chips, and another integrated circuits or devices. Plasma processing involves energizing a gas mixture by imparting energy to the gas molecules by the introduction of radio frequency (RF) energy into the gas mixture. This gas mixture is typically contained in a vacuum chamber, also called a plasma chamber. The semiconductor wafer is situated within the plasma chamber. RF energy is introduced through electrodes or other means in the chamber. In a typical plasma process, an RF source generates power at the desired RF frequency and power, and this power is transmitted to the plasma chamber. To provide efficient transfer of power from the RF source to the plasma chamber, a matching network is positioned between the RF source and the plasma chamber.

Different conditions within the plasma chamber (such as gas type, gas pressure, gas flow rate, wafer temperature, etc.) result in different electrical impedances at the RF input of the plasma chamber. The RF source generates the RF power which is transmitted to the RF matching network through a suitable RF connection (e.g., an RF coaxial cable). The matching network adjusts its internal component settings such that it can deliver maximum amount of the RF power generated by the RF generator to the plasma chamber. The gaseous plasma resulting from the RF power fed into the chamber then reacts with the wafer surface and etches or deposits material on the wafer.

In a deposition system, each time a process is run on a semiconductor wafer, the conditions within the plasma chamber change slightly. This can be due to the change in the condition of the plasma chamber walls, as by-products of the process gases coat the chamber walls. These changes in the condition of the plasma chamber, in turn, impact the process resulting in a wafer-to-wafer variation in the thickness of the deposited film. To overcome this variation, the plasma chamber goes through periodic maintenance to keep the deposited film thickness within acceptable range. Frequent preventive maintenance cycles, however, can reduce the uptime of the processing equipment and impact the operating cost of the system.

### BRIEF SUMMARY

In one aspect, the present disclosure may be directed to a system for adjustment of radio frequency (RF) power delivered to a plasma chamber, the system comprising a matching network configured to be coupled between an RF source and a plasma chamber; one or more memory devices configured to store first correlation data, the first correlation data based on film thickness values and, for each film thickness value, a corresponding matching network value, wherein each matching network value is a value, position, or setting for a parameter associated with the matching network; and store second correlation data, the second correlation data based on film thickness values and, for each film thickness value, a corresponding RF power setting for the RF source; and a control circuit operably coupled to the one or more memory devices, the control circuit configured to for a current wafer run for a semiconductor wafer, determine a current matching network value for the parameter associated with the matching network; using the current matching network value and the first correlation data, determine a current film thickness for the semiconductor wafer of the current wafer run; using the current film thickness and the second correlation data, determine the corresponding RF power setting for the RF source; and transmit a control signal to the RF source to cause an adjustment of the RF power being output by the RF source based on the corresponding RF power setting to achieve a new film thickness for the semiconductor wafer of the current wafer run that is within a desired film thickness range.

In another aspect, a method for adjustment of RF power delivered to a plasma chamber is disclosed. The method comprises storing or accessing first correlation data, the first correlation data based on film thickness values and, for each film thickness value, a corresponding matching network value, wherein each matching network value is a value for a parameter associated with a matching network coupled between an RF source and a plasma chamber; storing or accessing second correlation data, the second correlation data based on film thickness values and, for each film thickness value, a corresponding RF power setting for the RF source; for a current wafer run for a semiconductor wafer, determining a current matching network value for the parameter associated with the matching network; using the current matching network value and the first correlation data, determining a current film thickness for the semiconductor wafer of the current wafer run; using the current film thickness and the second correlation data, determining the corresponding RF power setting for the RF source; and causing adjustment of the RF power being output by the RF source based on the corresponding RF power setting to achieve a new film thickness for the semiconductor wafer of the current wafer run that is within a desired film thickness range.

In another aspect, a system for adjustment of RF power delivered to a plasma chamber is disclosed, the system comprising a matching network configured to be coupled between an RF source and a plasma chamber; one or more memory devices configured to store correlation data based on film thickness values and, for each film thickness value, a corresponding matching network value, wherein each matching network value is a value for a parameter associated with the matching network; and for each film thickness value, a corresponding RF power setting for the RF source; and a control circuit operably coupled to the one or more memory devices, the control circuit configured to for a current wafer run for a semiconductor wafer, determine a current matching network value for the parameter associated with the matching network; using the current matching network value and the correlation data, determine the corresponding RF power setting; and transmit a control signal to cause an adjustment of an RF power being delivered to the plasma chamber based on the corresponding RF power setting to achieve a new film thickness for the semiconductor wafer of the current wafer run that is within a desired film thickness range.

### BRIEF DESCRIPTION OF THE DRAWINGS

The present disclosure will become more fully understood from the detailed description and the accompanying drawings, wherein:

FIG. 1 is a block diagram of an embodiment of a semiconductor processing system, including a system for controlling a matching network of the semiconductor processing system;

FIG. 2 is a block diagram of an embodiment of a semiconductor processing system having an L-configuration matching network;

FIG. 3 is a block diagram of an embodiment of a semiconductor processing system having a pi-configuration matching network;

FIG. 4 is a block diagram of an embodiment of an electronic circuit for providing a variable capacitance using an electronically variable capacitor having two capacitor arrays;

FIG. 5 is a block diagram of an embodiment of a variable capacitance system for switching in and out discrete capacitors of an electronically variable capacitor;

FIG. 6 is a flow chart showing an embodiment of a process for matching an impedance by altering a variable capacitance;

FIG. 7 is a graph showing a correlation between film thickness and a capacitor position for a first variable capacitor of a matching circuit according to one embodiment.

FIG. 8 is a graph showing a correlation between film thickness and a capacitor position for a second variable capacitor of a matching circuit according to one embodiment.

FIG. 9 is a flow chart for a method of adjusting RF power delivered to a plasma chamber according to one embodiment.

### DETAILED DESCRIPTION

The following description of the preferred embodiment(s) is merely exemplary in nature and is in no way intended to limit the invention or inventions. The description of illustrative embodiments is intended to be read in connection with the accompanying drawings, which are to be considered part of the entire written description. In the description of the exemplary embodiments disclosed herein, any reference to direction or orientation is merely intended for convenience of description and is not intended in any way to limit the scope of the present inventions. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to an interpretation of “based entirely on.”

Features of the present inventions may be implemented in software, hardware, firmware, or combinations thereof. The computer programs described herein are not limited to any particular embodiment, and may be implemented in an operating system, application program, foreground or background processes, driver, or any combination thereof. The computer programs may be executed on a single computer or server processor or multiple computer or server processors.

Processors described herein may be any central processing unit (CPU), microprocessor, micro-controller, computational, or programmable device or circuit configured for executing computer program instructions (e.g., code). Various processors may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc.

Computer-executable instructions or programs (e.g., software or code) and data described herein may be programmed into and tangibly embodied in a non-transitory computer-readable medium that is accessible to and retrievable by a respective processor as described herein which configures and directs the processor to perform the desired functions and processes by executing the instructions encoded in the medium. A device embodying a programmable processor configured to such non-transitory computer-executable instructions or programs may be referred to as a “programmable device”, or “device”, and multiple programmable devices in mutual communication may be referred to as a “programmable system.” It should be noted that non-transitory “computer-readable medium” as described herein may include, without limitation, any suitable volatile or non-volatile memory including random access memory (RAM) and various types thereof, read-only memory (ROM) and various types thereof, USB flash memory, and magnetic or optical data storage devices (e.g., internal/external hard disks, floppy discs, magnetic tape CD-ROM, DVD-ROM, optical disk, ZIP™ drive, Blu-ray disk, and others), which may be written to and/or read by a processor operably connected to the medium.

In certain embodiments, the present invention may be embodied in the form of computer-implemented processes and apparatuses such as processor-based data processing and communication systems or computer systems for practicing those processes. The present invention may also be embodied in the form of software or computer program code embodied in a non-transitory computer-readable storage medium, which when loaded into and executed by the data processing and communications systems or computer systems, the computer program code segments configure the processor to create specific logic circuits configured for implementing the processes.

As used throughout, ranges are used as shorthand for describing each and every value that is within the range. Any value within the range can be selected as the terminus of the range. In addition, all references cited herein are hereby incorporated by referenced in their entireties. In the event of a conflict in a definition in the present disclosure and that of a cited reference, the present disclosure controls.

In the following description, where circuits are shown and described, one of skill in the art will recognize that, for the sake of clarity, not all peripheral circuits or components are shown in the figures or described in the description. Further, the terms “couple” and “operably couple” can refer to a direct or indirect coupling of two components of a circuit.

The following description of the preferred embodiment(s) is merely exemplary in nature and is in no way intended to limit the invention or inventions. The description of illustrative embodiments is intended to be read in connection with the accompanying drawings, which are to be considered part of the entire written description. In the description of the exemplary embodiments disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top,” “bottom,” “front” and “rear” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” “secured” and other similar terms refer to a relationship wherein structures are secured or attached to one another either directly or indirectly through intervening structures, as well as both movable or rigid attachments or relationships, unless expressly described otherwise. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to an interpretation of “based entirely on.”

As used throughout, ranges are used as shorthand for describing each and every value that is within the range. Any value within the range can be selected as the terminus of the range. In addition, all references cited herein are hereby incorporated by referenced in their entireties. In the event of a conflict in a definition in the present disclosure and that of a cited reference, the present disclosure controls.

### Semiconductor Processing System

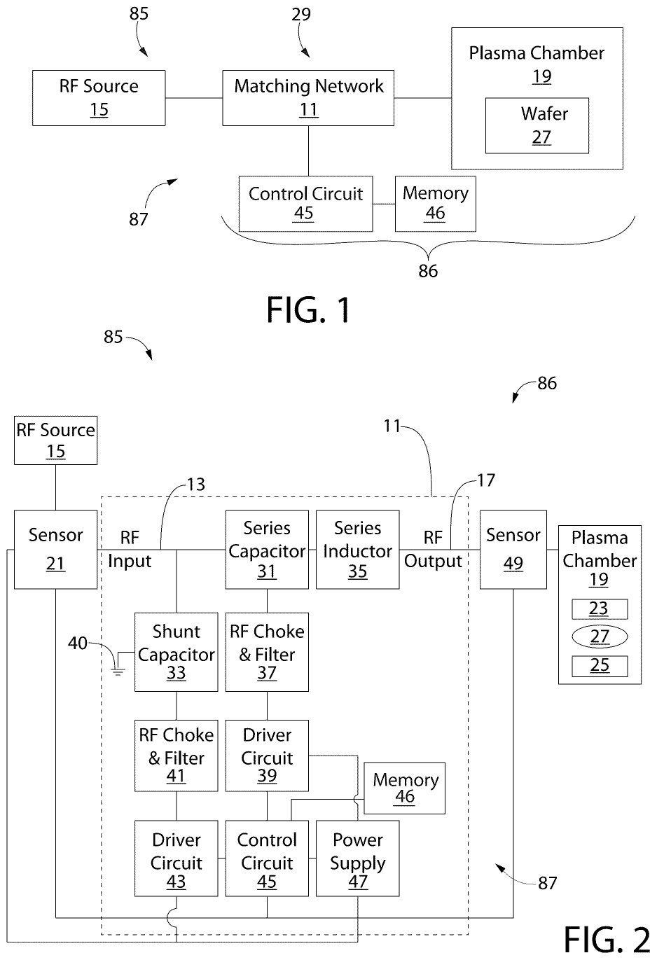

Referring to FIG. 1, a semiconductor device processing system 85 utilizing an RF source 15 is shown. The system 85 includes an RF source 15 and a semiconductor processing tool 86. The semiconductor processing tool 86 includes a matching network 11 and a plasma chamber 19. In other embodiments, the RF source 15 or other power source can form part of the semiconductor processing tool. For the semiconductor processing systems and their components (e.g., matching networks, EVCs, and EVREs) discussed herein, applicant incorporates by reference in its entirety U.S. Pub. No. 2024/0177970.

The semiconductor device can be a microprocessor, a memory chip, or other type of integrated circuit or device. A silicon wafer 27 can be placed in the plasma chamber 19, where the plasma chamber 19 is configured to deposit a material layer onto the wafer 27 or etch a material layer from the wafer 27. Plasma processing involves energizing a gas mixture by imparting energy to the gas molecules by introducing RF energy into the gas mixture. This gas mixture is typically contained in a vacuum chamber (the plasma chamber 19), and the RF energy is typically introduced into the plasma chamber 19 through electrodes. Thus, the plasma can be energized by coupling RF power from an RF source 15 into the plasma chamber 19 to perform deposition or etching.

### Matching Network

In a typical plasma process, the RF source 15 generates power at a radio frequency—which is typically within the range of 3 kHz and 300 GHz—and this power is transmitted through RF cables and networks to the plasma chamber 19. To provide efficient transfer of power from the RF source 15 to the plasma chamber 19, an intermediary circuit is used to match the fixed impedance of the RF source 15 with the variable impedance of the plasma chamber 19. Such an intermediary circuit is commonly referred to as an RF impedance matching network, or more simply as a matching network or matching circuit. The purpose of the matching network 11 is to transform the variable plasma impedance to a value that more closely matches the fixed impedance of the RF source 15. Commonly owned U.S. patent application Ser. No. 14/669,568, the disclosure of which is incorporated herein by reference in its entirety, provides an example of such a matching network.

FIG. 2 is a block diagram of an embodiment of a semiconductor processing system 85 having a semiconductor processing tool 86 that includes an L-configuration matching network 11. The matching network 11 has an RF input 13 connected to an RF source 15 and an RF output 17 connected to a plasma chamber 19. An RF input sensor 21 can be connected between the matching network 11 and the RF source 15. An RF output sensor 49 can be connected between the matching network 11 and the plasma chamber 19 so that the RF output from the impedance matching network, and the plasma impedance presented by the plasma chamber 19, may be monitored. Certain embodiments may include only one of the input sensor 21 and the output sensor 49. The functioning of these sensors 21, 49 are described in greater detail below.

As discussed above, the matching network 11 serves to help maximize the amount of RF power transferred from the RF source 15 to the plasma chamber 19 by matching the impedance at the RF input 13 to the fixed impedance of the RF source 15. The matching network 11 can consist of a single module within a single housing designed for electrical connection to the RF source 15 and plasma chamber 19. In other embodiments, the components of the matching network 11 can be located in different housings, some components can be outside of the housing, and/or some components can share a housing with a component outside the matching network.

The plasma within the plasma chamber 19 typically undergoes certain fluctuations outside of operational control so that the impedance presented by the plasma chamber 19 is a variable impedance. Since the variable impedance of the plasma chamber 19 cannot be fully controlled, an impedance matching network may be used to create an impedance match between the plasma chamber 19 and the RF source 15. Moreover, the impedance of the RF source 15 may be fixed at a set value by the design of the particular RF source 15. Although the fixed impedance of the RF source 15 may undergo minor fluctuations during use, due to, for example, temperature or other environmental variations, the impedance of the RF source 15 is still considered a fixed impedance for purposes of impedance matching because the fluctuations do not significantly vary the fixed impedance from the originally set impedance value. Other types of RF source 15 may be designed so that the impedance of the RF source 15 may be set at the time of, or during, use. The impedance of such types of RF sources 15 is still considered fixed because it may be controlled by a user (or at least controlled by a programmable controller) and the set value of the impedance may be known at any time during operation, thus making the set value effectively a fixed impedance.

The RF source 15 may comprise an RF generator configured to generate an RF signal at an appropriate frequency and power for the process performed within the plasma chamber 19. The RF source 15 may be electrically connected to the RF input 13 of the matching network 11 using a coaxial cable, which for impedance matching purposes would have the same fixed impedance as the RF source 15.

The plasma chamber 19 includes a first electrode 23 and a second electrode 25, and in processes that are well known in the art, the first and second electrodes 23, 25, in conjunction with appropriate control systems (not shown) and the plasma in the plasma chamber 19, enable one or both of deposition of materials onto a wafer 27 and etching of materials from the wafer 27.

In the exemplified embodiment, the matching network 11 includes a series variable capacitor 31, a shunt variable capacitor 33, and a series inductor 35 to form an ‘L’ type matching network. The shunt variable capacitor 33 is shown shunting to a reference potential, which in this embodiment is ground 40.

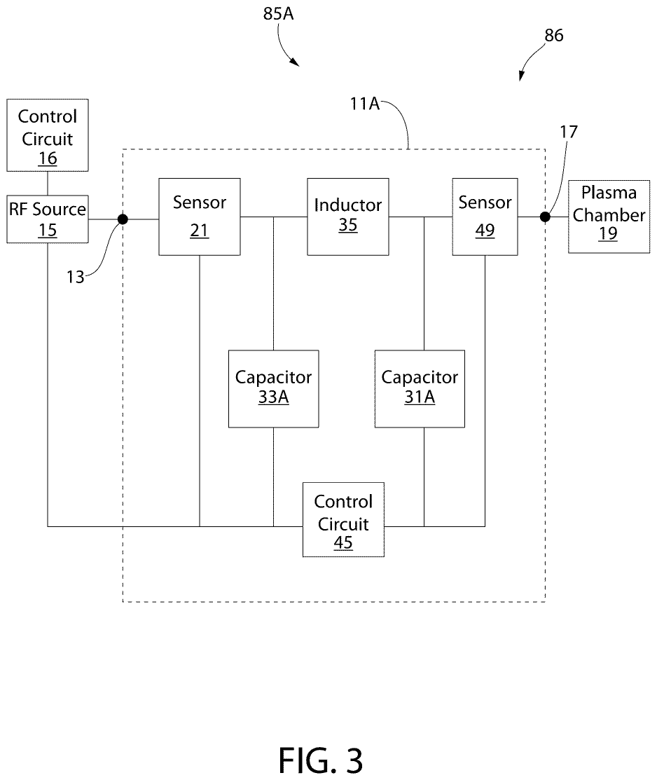

Alternatively, the matching network 11 may be configured in other matching network configurations, such as a ‘T’ type configuration or a ‘Π’ or ‘pi’ type configuration, as will be shown in FIG. 3. In certain embodiments, the variable capacitors and the switching circuit described below may be included in any configuration appropriate for a matching network.

In the exemplified embodiment, and referring to FIG. 2, each of the series variable capacitor 31 and the shunt variable capacitor 33 may be an electronic variable capacitor (EVC), as described in U.S. Pat. No. 7,251,121, the EVC being effectively formed as a capacitor array formed by a plurality of discrete capacitors. The series variable capacitor 31 is coupled in series between the RF input 13 and the RF output 17 (which is also in parallel between the RF source 15 and the plasma chamber 19). The shunt variable capacitor 33 is coupled between the RF input 13 and ground 40. In other configurations, the shunt variable capacitor 33 may be coupled in parallel between the RF output 19 and ground 40. Other configurations may also be implemented without departing from the functionality of a matching network. In still other configurations, the shunt variable capacitor 33 may be coupled in parallel between a reference potential and one of the RF input 13 and the RF output 19.

The series variable capacitor 31 is connected to a series RF choke and filter circuit 37 and to a series driver circuit 39. Similarly, the shunt variable capacitor 33 is connected to a shunt RF choke and filter circuit 41 and to a shunt driver circuit 43. Each of the series and shunt driver circuits 39, 43 are connected to a control circuit 45, which is configured with an appropriate processor and/or signal generating circuitry to provide an input signal for controlling the series and shunt driver circuits 39, 43. A power supply 47 is connected to each of the RF input sensor 21, the series driver circuit 39, the shunt driver circuit 43, and the control circuit 45 to provide operational power, at the designed currents and voltages, to each of these components. The voltage levels provided by the power supply 47, and thus the voltage levels employed by each of the RF input sensor 21, the series driver circuit 39, the shunt driver circuit 43, and the control circuit 45 to perform the respective designated tasks, is a matter of design choice. In other embodiments, a variety of electronic components can be used to enable the control circuit 45 to send instructions to the variable capacitors. Further, while the driver circuit 39, 43 and RF choke and filter 37, 41 are shown as separate from the control circuit 45, these components can also be considered as forming part of the control circuit 45. The control circuit 45 may include or be coupled to a memory 46. The memory 46 may store instructions for the control circuit 45 as well as other data that the control circuit 45 may utilize.

In the exemplified embodiment, the control circuit 45 includes a processor. The processor may be any type of properly programmed processing device, such as a computer or microprocessor, configured for executing computer program instructions (e.g., code). The processor may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage (such as volatile and non-volatile memory), input/output devices, graphical user interfaces (GUIs), removable data storage, and wired and/or wireless communication interface devices including Wi-Fi, Bluetooth, LAN, etc. The processor of the exemplified embodiment is configured with specific algorithms to enable the matching network 11 to perform the functions described herein.

With the combination of the series variable capacitor 31 and the shunt variable capacitor 33, the combined impedances of the matching network 11 and the plasma chamber 19 may be controlled, using the control circuit 45, the series driver circuit 39, the shunt driver circuit 43, to match, or at least to substantially match, the fixed impedance of the RF source 15.

The control circuit 45 operates the matching network 11, as it receives multiple inputs, from sources such as the RF input sensor 21 and the series and shunt variable capacitors 31, 33, makes the calculations necessary to determine changes to the series and shunt variable capacitors 31, 33, and delivers commands to the series and shunt variable capacitors 31, 33 to create the impedance match. The control circuit 45 is of the type of control circuit that is commonly used in semiconductor fabrication processes, and therefore known to those of skill in the art. Any differences in the control circuit 45, as compared to control circuits of the prior art, arise in programming differences to account for the speeds at which the matching network 11 is able to perform switching of the variable capacitors 31, 33 and impedance matching.

Each of the series and shunt RF choke and filter circuits 37, 41 are configured so that DC signals may pass between the series and shunt driver circuits 39, 43 and the respective series and shunt variable capacitors 31, 33, while at the same time, the RF signal from the RF source 15 is blocked to prevent the RF signal from leaking into the outputs of the series and shunt driver circuits 39, 43 and the output of the control circuit 45. The series and shunt RF choke and filter circuits 37, 41 are of a type known to those of skill in the art.

FIG. 3 is a block diagram of an embodiment of a semiconductor processing system 85A having a pi-configuration matching network 11A, as opposed to the L-configuration matching network of FIG. 2. For ease of understanding, this figure omits the RF chokes and filters, driver circuits, and power supplies of FIG. 2. Where FIG. 3 uses reference numbers identical to those of FIG. 2, it is understood that the relevant components can have features similar to those discussed with regard to FIG. 2.

The most significant difference between the L- and pi-configuration is that the L-configuration utilizes a series capacitor 31 and shunt capacitor 33, while the pi-configuration utilizes two shunt capacitors 31A, 33A. Nevertheless, the control circuit 45 can alter the capacitance of these shunt variable capacitors 31A, 33A to cause an impedance match. Each of these shunt variable capacitors 31A, 33A can be an EVC, as discussed above. They can be controlled by a choke, filter, and driver similar to the methods discussed above with respect to FIG. 2.

### EVC Capacitor Arrays

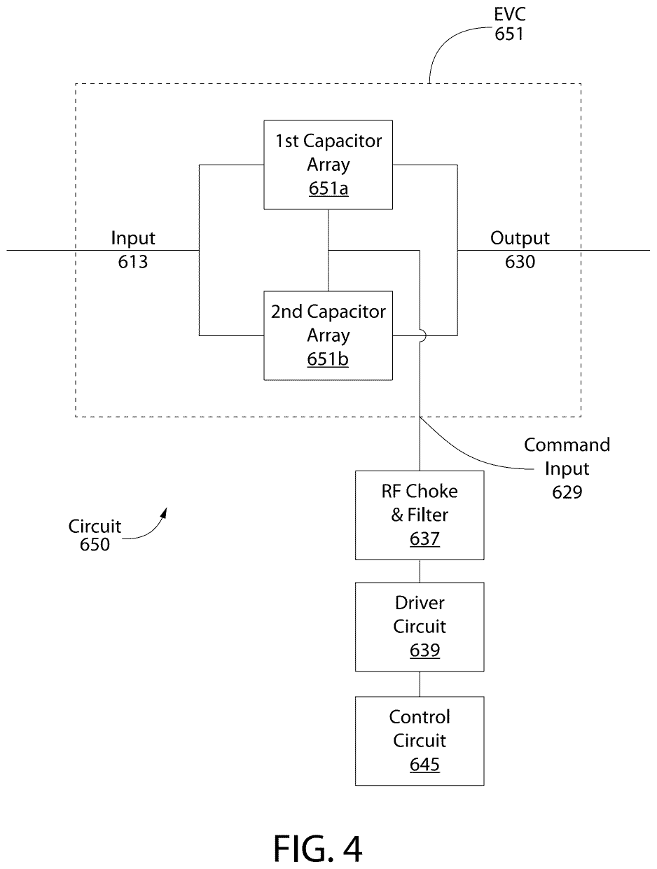

FIG. 4 shows an electronic circuit 650 for providing a variable capacitance according to one embodiment. The circuit 650 utilizes an EVC 651 that includes two capacitor arrays 651a, 651b. The first capacitor array 651a may comprise a plurality of first plurality of discrete capacitors, each having a first capacitance value. The second capacitor array 651b may comprise a plurality of second plurality of discrete capacitors, each having a second capacitance value. The first capacitance value is different from the second capacitance value, such that the EVC 651 can provide coarse and fine control of the capacitance produced by the EVC 651. The first capacitor array 651a and the second capacitor array 651b are coupled in parallel between a signal input 613 and a signal output 630.

The first and second capacitance values can be any values sufficient to provide the desired overall capacitance values for the EVC 651. In one embodiment, the second capacitance value is less than or equal to one-half (½) of the first capacitance value. In another embodiment, the second capacitance value is less than or equal to one-third (⅓) of the first capacitance value. In yet another embodiment, the second capacitance value is less than or equal to one-fourth (¼) of the first capacitance value.

The electronic circuit 650 further includes a control circuit 645, which can have features similar to control circuit 45 discussed above. The control circuit 645 is operably coupled to the first capacitor array 651a and to the second capacitor array 651b by a command input 629, the command input 629 being operably coupled to the first capacitor array 651a and to the second capacitor array 651b. In the exemplified embodiment, the command input 629 has a direct electrical connection to the capacitor arrays 651a, 651b, though in other embodiments this connection can be indirect. The coupling of the control circuit 645 to the capacitor arrays 651a, 651b will be discussed in further detail below.

The control circuit 645 is configured to alter the variable capacitance of the EVC 651 by controlling on and off states of (a) each discrete capacitor of the first plurality of discrete capacitors 651a and (b) each discrete capacitor of the second plurality of discrete capacitors 651b. As stated above, the control circuit 645 can have features similar to those described with respect to control circuit 45 of FIGS. 2-3. For example, the control circuit 645 can receive inputs from the capacitor arrays 651a, 651b, make calculations to determine changes to the capacitor arrays 651a, 651b, and delivers commands to the capacitor arrays 651a, 651b for altering the capacitance of the EVC 651. EVC 651 of FIG. 4 can include a plurality of electronic switches. Each electronic switch can be configured to activate and deactivate one or more discrete capacitors.

As with the control circuit 45 of FIGS. 2-3, the control circuit 645 can also be connected to a driver circuit 639 and an RF choke and filter circuit 637. The control circuit 645, driver circuit 639, and RF choke and filter circuit 637 can have capabilities similar to those discussed with regard to FIGS. 2-3. In the exemplified embodiment, the driver circuit 639 is operatively coupled between the control circuit 645 and the first and second capacitor arrays 651a, 651b. The driver circuit 639 is configured to alter the variable capacitance based upon a control signal received from the control circuit 645. The RF filter 637 is operatively coupled between the driver circuit 639 and the first and second capacitor arrays 651a, 651b. In response to the control signal sent by the control unit 645, the driver circuit 639 and RF filter 637 are configured to send a command signal to the command input 629. The command signal is configured to alter the variable capacitance by instructing at least one of the electronic switches to activate or deactivate (a) at least one the discrete capacitors of the first plurality of discrete capacitors or (b) at least one of the discrete capacitors of the second plurality of discrete capacitors.

In the exemplified embodiment, the driver circuit 639 is configured to switch a high voltage source on or off in less than 15 μsec, the high voltage source controlling the electronic switches of each of the first and second capacitor arrays for purposes of altering the variable capacitance. The EVC 651, however, can be switched by any of the means or speeds discussed in the present application.

The control circuit 645 can be configured to calculate coarse and fine capacitance values to be provided by the respective capacitor arrays 651a, 651b. In the exemplified embodiment, the control circuit 645 is configured to calculate a coarse capacitance value to be provided by controlling the on and off states of the first capacitor array 651a. Further, the control circuit is configured to calculate a fine capacitance value to be provided by controlling the on and off states of the second capacitor array 651b. In other embodiments, the capacitor arrays 651a, 651b can provide alternative levels of capacitance. In other embodiments, the EVC can utilize additional capacitor arrays.

EVC 651 of FIG. 4 can be used in most systems requiring a varying capacitance. For example, EVC 651 can be used as the series EVC and/or shunt EVC in matching network 11 of FIG. 2, or as one or both of the shunt EVCs in matching network 11A of FIG. 3. It is often desired that the differences between the capacitance values allow for both a sufficiently fine resolution of the overall capacitance of the circuit and a wide range of capacitance values to enable a better impedance match at the input of a matching network, and EVC 651 allows this.

EVC 651 can also be used in a system or method for fabricating a semiconductor, a method for controlling a variable capacitance, and/or a method of controlling a matching network. Such methods can include altering at least one of the series variable capacitance and the shunt variable capacitance to the determined series capacitance value and the shunt capacitance value, respectively. This altering can be accomplishing by controlling, for each of the series EVC and the shunt EVC, on and off states of each discrete capacitor of each plurality of discrete capacitors. In other embodiments, EVC 651 and circuit 650 can be used in other methods and systems to provide a variable capacitance.

### Switching in and Out Discrete Capacitors to Vary EVC Capacitance

As discussed above, an EVC is a type of variable capacitor that can use multiple switches, each used to create an open or short circuit, with individual series capacitors to change the capacitance of the variable capacitor. The switches can be mechanical (such as relays) or solid state (such as PIN diodes, transistors, or other switching devices). The following is a discussion of methods for setting up an EVC or other variable capacitor to provide varying capacitances.

In what is sometimes referred to as an “accumulative setup” of an EVC or other variable capacitor, the approach to linearly increase the capacitor value from the minimum starting point (where all switches are open) is to incrementally increase the number of fine tune capacitors that are switched into the circuit. Once the maximum number of fine tune capacitors is switched into circuit, a coarse tune capacitor is switched in, and the fine tune capacitors are switched out. The process starts over with increasing the number of fine tune capacitors that are switched into circuit, until all fine and coarse tune capacitors are switched in, at which point another coarse tune capacitor is switched in and the fine tune capacitors are switched out. This process can continue until all the coarse and fine capacitors are switched in.

In this embodiment, all of the fine tune capacitors have the same or a substantially similar value, and all the coarse tune capacitors have the same or a substantially similar value. Further, the capacitance value of one coarse tune capacitor about equals the combined capacitance value of all fine tune capacitors plus an additional fine tune capacitor into the circuit, thus enabling a linear increase in capacitance. The embodiments, however, are not so limited. The fine tune capacitors (and coarse capacitors) need not have the same or a substantially similar value. Further, the capacitance value of one coarse tune capacitor need not equal the combined capacitance value of all fine tune capacitors plus an additional fine tune capacitor. In one embodiment, the coarse capacitance value and the fine capacitance value have a ratio substantially similar to 10:1. In another embodiment, the second capacitance value is less than or equal to one-half (½) of the first capacitance value. In another embodiment, the second capacitance value is less than or equal to one-third (⅓) of the first capacitance value. In yet another embodiment, the second capacitance value is less than or equal to one-fourth (¼) of the first capacitance value.

An example of the aforementioned embodiment in an ideal setting would be if the fine tune capacitors were equal to 1 pF, and the coarse tune capacitors were equal to 10 pF. In this ideal setup, when all switches are open, the capacitance is equal to 0 pF. When the first switch is closed, there is 1 pF in the circuit. When the second switch is closed there is 2 pF in the circuit, and so on, until nine fine tune switches are closed, giving 9 pF. Then, the first 10 pF capacitor is switched into circuit and the nine fine tune switches are opened, giving a total capacitance of 10 pF. The fine tune capacitors are then switched into circuit from 11 pF to 19 pF. Another coarse tune capacitor can then be switched into circuit and all fine tune capacitors can be switched out of circuit giving 20 pF. This process can be repeated until the desired capacitance is reached.

This can also be taken one step further. Using the previous example, having nine 1 pF capacitors and also nine 10 pF capacitors, the variable capacitor circuit can have even larger values, 100 pF, to switch in and out of circuit. This would allow the previous capacitor array to go up to 99 pF, and then the 100 pF capacitor can be used for the next increment. This can be repeated further using larger increments, and can also be used with any counting system. According to the accumulative setup, increasing the total capacitance of a variable capacitor is achieved by switching in more of the coarse capacitors or more of the fine capacitors than are already switched in without switching out a coarse capacitor that is already switched in. Further, when the variable total capacitance is increased and the control circuit does not switch in more of the coarse capacitors than are already switched in, then the control circuit switches in more fine capacitors than are already switched in without switching out a fine capacitor that is already switched in.

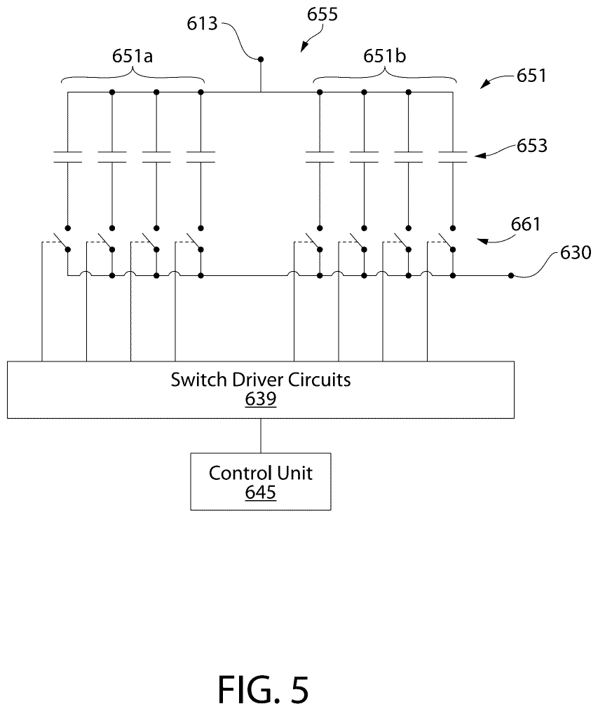

FIG. 5 is a schematic of a variable capacitance system 655 according to an accumulative setup. Where this figure uses reference numbers identical to those of FIG. 4, it is understood that the relevant components can have features similar to those discussed in FIG. 4. The variable capacitance system 655 comprises a variable capacitor 651 for providing a varying capacitance. The variable capacitor 651 has an input 613 and an output 630. The variable capacitor 651 includes a plurality of discrete capacitors 653 operably coupled in parallel. The plurality of capacitors 653 includes first (fine) capacitors 651a and second (coarse) capacitors 651B. Further, the variable capacitor 651 includes a plurality of switches 661. Of the switches 661, one switch is operably coupled in series to each of the plurality of capacitors to switch in and out each capacitor, thereby enabling the variable capacitor 651 to provide varying total capacitances. The variable capacitor 651 has a variable total capacitance that is increased when discrete capacitors 653 are switched in and decreased when the discrete capacitors 653 are switched out.

The switches 661 can be coupled to switch driver circuits 639 for driving the switches on and off. The variable capacitance system 655 can further include a control unit 645 operably coupled to the variable capacitor 651. Specifically, the control unit 645 can be operably coupled to the driver circuits 639 for instructing the driver circuits 639 to switch one or more of the switches 661, and thereby turn one or more of the capacitors 653 on or off. In one embodiment, the control unit 645 can form part of a control unit that controls a variable capacitor, such as a control unit that instructs the variable capacitors of a matching network to change capacitances to achieve an impedance match. The driver circuits 639 and control unit 645 can have features similar to those discussed above with reference to FIG. 4, and thus can also utilize an RF choke and filter as discussed above.

In one embodiment, the control circuit 645 is configured to determine a desired coarse capacitance for the coarse capacitors; determine a desired fine capacitance for the fine capacitors; and after calculating the desired coarse capacitance and the desired fine capacitance, alter the total variable capacitance by switching in or out at least one of the fine capacitors; and switching in or out at least one of the coarse capacitors. In other embodiments, coarse tuning and fine tuning can occur at different stages.

In the exemplified embodiment, the first capacitors 651a are fine capacitors each having a capacitance value substantially similar to a fine capacitance value, and the second capacitors 651b are coarse capacitors each having a capacitance value substantially similar to a coarse capacitance value, the coarse capacitance value being greater than the fine capacitance value. For purposes of this application, capacitances and other values are considered to be substantially similar if one value is not 15 percent (15%) greater than or less than another value.

The variable capacitance system 655 can form part of an impedance matching network, including but not limited to, the impedance matching networks of FIGS. 1-3. The variable capacitance system can also form part of a method for controlling an impedance matching network (such as the impedance matching networks of FIGS. 1-3). The method can include providing the matching network comprising determining an increased total capacitance to be provided by one of the EVCs; and increasing the variable total capacitance of the one EVC by switching in more of the coarse capacitors or more of the fine capacitors than are already switched in without switching out a coarse capacitor that is already switched in. Further, the variable capacitance system can form part of a method and system for fabricating a semiconductor (see FIGS. 1-3).

Using the variable capacitance system discussed above with an impedance matching network can provide several advantages over other approaches. An alternative to the above approach would be to have all the capacitor values be different, with the first value equal to the minimum desired change in capacitance. Then each successive capacitor value is increased to double the change in capacitance from the previous up until the maximum desired capacitor value, when all capacitors are switched in. This approach can result in using less capacitors to switch in and out of circuit to achieve the same resolution and range. A potential problem with this setup, however, is that, once the capacitor reaches a certain value, the voltage and/or current on that particular capacitor or the current on the switch can be higher than the specification allows for. This forces the EVC to use multiple capacitors in parallel for each switch of lower value. This problem is particularly acute where high voltages and/or currents are being used. The accumulative setup discussed above avoids putting this degree of stress on its capacitors and switches by switching in additional capacitors, rather than replacing lower-capacitance capacitors with higher-capacitance capacitors.

### Determining Capacitance Values to Achieve Match

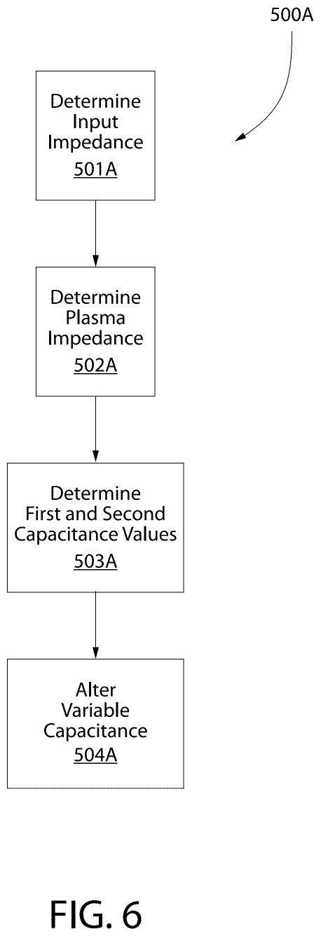

FIG. 6 is a flow chart showing a process 500A for matching an impedance according to one embodiment. The matching network can include components similar to those discussed above. In one embodiment, the matching network of FIG. 2 is utilized. In the first step of the exemplified process 500A of FIG. 6, an input impedance at the RF input 13 is determined (step 501A). The input impedance is based on the RF input parameter detected by the RF input sensor 21 at the RF input 13. The RF input sensor 21 can be any sensor configured to detect an RF input parameter at the RF input 13. The input parameter can be any parameter measurable at the RF input 13, including a voltage, a current, or a phase at the RF input 13. In the exemplified embodiment, the RF input sensor 21 detects the voltage, current, and phase at the RF input 13 of the matching network 11. Based on the RF input parameter detected by the RF input sensor 21, the control circuit 45 determines the input impedance.

Next, the control circuit 45 determines the plasma impedance presented by the plasma chamber 19 (step 502A). In one embodiment, the plasma impedance determination is based on the input impedance (determined in step 501A), the capacitance of the series EVC 31, and the capacitance of the shunt EVC 33. In other embodiments, the plasma impedance determination can be made using the output sensor 49 operably coupled to the RF output, the RF output sensor 49 configured to detect an RF output parameter. The RF output parameter can be any parameter measurable at the RF output 17, including a voltage, a current, or a phase at the RF output 17. The RF output sensor 49 may detect the output parameter at the RF output 17 of the matching network 11. Based on the RF output parameter detected by the RF output sensor 21, the control circuit 45 may determine the plasma impedance. In yet other embodiments, the plasma impedance determination can be based on both the RF output parameter and the RF input parameter.

Once the variable impedance of the plasma chamber 19 is known, the control circuit 45 can determine the changes to make to the variable capacitances of one or both of the series and shunt EVCs 31, 33 for purposes of achieving an impedance match. Specifically, the control circuit 45 determines a first capacitance value for the series variable capacitance and a second capacitance value for the shunt variable capacitance (step 503A). These values represent the new capacitance values for the series EVC 31 and shunt EVC 33 to enable an impedance match, or at least a substantial impedance match. In the exemplified embodiment, the determination of the first and second capacitance values is based on the variable plasma impedance (determined in step 502A) and the fixed RF source impedance.

Once the first and second capacitance values are determined, the control circuit 45 generates a control signal to alter at least one of the series variable capacitance and the shunt variable capacitance to the first capacitance value and the second capacitance value, respectively (step 504A). This is done at approximately t=−5 μsec. The control signal instructs the switching circuit to alter the variable capacitance of one or both of the series and shunt EVCs 31, 33.

This alteration of the EVCs 31, 33 takes about 9-11 μsec total, as compared to about 1-2 sec of time for a matching network using VVCs. Once the switch to the different variable capacitances is complete, there is a period of latency as the additional discrete capacitors that make up the EVCs join the circuit and charge. This part of the match tune process takes about 55 μsec. Finally, the RF power profile 403 is shown decreasing, at just before t=56 μsec, from about 380 mV peak-to-peak to about 100 mV peak-to-peak. This decrease in the RF power profile 403 represents the decrease in the reflected power 407, and it takes place over a time period of about 10 μsec, at which point the match tune process is considered complete.

The altering of the series variable capacitance and the shunt variable capacitance can comprise sending a control signal to the series driver circuit 39 and the shunt driver circuit 43 to control the series variable capacitance and the shunt variable capacitance, respectively, where the series driver circuit 39 is operatively coupled to the series EVC 31, and the shunt driver circuit 43 is operatively coupled to the shunt EVC 43. When the EVCs 31, 33 are switched to their desired capacitance values, the input impedance may match the fixed RF source impedance (e.g., 50 Ohms), thus resulting in an impedance match. If, due to fluctuations in the plasma impedance, a sufficient impedance match does not result, the process of 500A may be repeated one or more times to achieve an impedance match, or at least a substantial impedance match.

Using a matching network 11, such as that shown in FIG. 2, the input impedance can be represented as follows:

$${Z}_{in} = \frac{( {Z}_{P} + {Z}_{L} + {Z}_{series} ) {Z}_{shunt}}{{Z}_{P} + {Z}_{L} + {Z}_{series} + {Z}_{shunt}}$$

where Zᵢₙ is the input impedance, Z_{P} is the plasma impedance, Z_{L} is the series inductor impedance, Zₛₑᵣᵢₑₛ is the series EVC impedance, and Zₛₕᵤₙₜ is the shunt EVC impedance. In the exemplified embodiment, the input impedance (Zᵢₙ) is determined using the RF input sensor 21. The EVC impedances (Zₛₑᵣᵢₑₛ and Zₛₕᵤₙₜ) are known at any given time by the control circuitry, since the control circuitry is used to command the various discrete capacitors of each of the series and shunt EVCs to turn ON or OFF. Further, the series inductor impedance (Z_{L}) is a fixed value. Thus, the system can use these values to solve for the plasma impedance (Z_{P}).

Based on this determined plasma impedance (Z_{P}) and the known desired input impedance (Zᵢₙ′) (which is typically 50 Ohms), and the known series inductor impedance (Z_{L}), the system can determine a new series EVC impedance

$$( {Z}_{series}^{′} )$$

and shunt EVC impedance

$$( {Z}_{shunt}^{′} ) .$$

$${Z}_{in}^{′} = \frac{( {Z}_{P} + {Z}_{L} + {Z}_{series}^{′} ) {Z}_{shunt}^{′}}{{Z}_{P} + {Z}_{L} + {Z}_{series}^{′} + {Z}_{shunt}^{′}}$$

Based on the newly calculated series EVC variable impedance

$$( {Z}_{series}^{′} )$$

and shunt EVC variable impedance

$$( {Z}_{shunt}^{′} ) ,$$

the system can then determine the new capacitance value (first capacitance value) for the series variable capacitance and a new capacitance value (second capacitance value) for the shunt variable capacitance. When these new capacitance values are used with the series EVC 31 and the shunt EVC 33, respectively, an impedance match may be accomplished.

The exemplified method of computing the desired first and second capacitance values and reaching those values in one step is significantly faster than moving the two EVCs step-by-step to bring either the error signals to zero, or to bring the reflected power/reflection coefficient to a minimum. In semiconductor plasma processing, where a faster tuning scheme is desired, this approach provides a significant improvement in matching network tune speed.

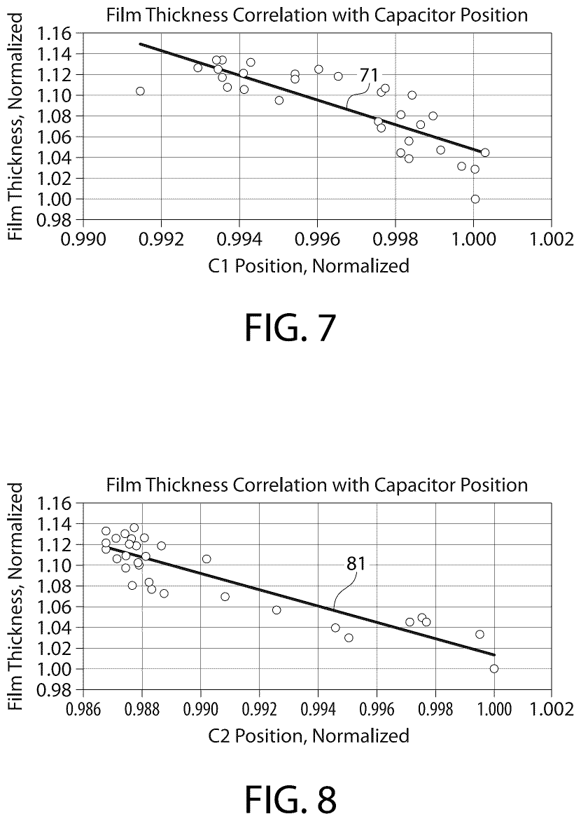

It is noted that the invention is not limited to the above process for matching an impedance. For example, the process could use a parameter matrix, as discussed in detail with respect to FIG. 7 of U.S. Pub. No. 2024/0177970, which is incorporated by reference herein in its entirety.

Those of skill in the art will recognize that several factors may contribute to the sub-millisecond elapsed time of the impedance matching process for a matching network using EVCs. Such factors may include the power of the RF signal, the configuration and design of the EVCs, the type of matching network being used, and the type and configuration of the driver circuit being used. Other factors not listed may also contribute to the overall elapsed time of the impedance matching process. Thus, it is expected that the entire match tune process for a matching network having EVCs should take no more than about 500 μsec to complete from the beginning of the process (i.e., measuring by the control circuit and calculating adjustments needed to create the impedance match) to the end of the process (the point in time when the efficiency of RF power coupled into the plasma chamber is increased due to an impedance match and a reduction of the reflected power). Even at a match tune process on the order of 500 μsec, this process time still represents a significant improvement over matching networks using VVCs.

Table 1 presents data showing a comparison between operational parameters of one example of an EVC versus one example of a VVC. As can be seen, EVCs present several advantages, in addition to enabling fast switching for a matching network:

TABLE 1

| | | | Typical 1000 pF | |
|---|---|---|---|---|
| Parameter | EVC | | Vacuum Capacitors | |
| Capacitance | 20 pF~1400 pF | | 15 pF~1000 pF | |
| Reliability | High | | Low | |
| Response Time | ~500 | μsec | 1 s~2 s | |
| ESR | ~13 | mW | ~20 | mW |
| Voltage | 7 | kV | 5 | kV |
| Current Handling Capability | 216 | A rms | 80 | A rms |
| Volume | 4.5 | in³ | 75 | in³ |

As is seen, in addition to the fast switching capabilities made possible by the EVC, EVCs also introduce a reliability advantage, a current handling advantage, and a size advantage. Additional advantages of the matching network using EVCs and/or the switching circuit itself for the EVCs include:
The disclosed matching network does not include any moving parts, so the likelihood of a mechanical failure reduced to that of other entirely electrical circuits which may be used as part of the semiconductor fabrication process. For example, the typical EVC may be formed from a rugged ceramic substrate with copper metallization to form the discrete capacitors. The elimination of moving parts also increases the resistance to breakdown due to thermal fluctuations during use.
The EVC has a compact size as compared to a VVC, so that the reduced weight and volume may save valuable space within a fabrication facility.
The design of the EVC introduces an increased ability to customize the matching network for specific design needs of a particular application. EVCs may be configured with custom capacitance ranges, one example of which is a non-linear capacitance range. Such custom capacitance ranges can provide better impedance matching for a wider range of processes. As another example, a custom capacitance range may provide more resolution in certain areas of impedance matching. A custom capacitance range may also enable generation of higher ignition voltages for easier plasma strikes.
The short match tune process (~500 μsec or less) allows the matching network to better keep up with plasma changes within the fabrication process, thereby increasing plasma stability and resulting in more controlled power to the fabrication process.
The use of EVCs, which are digitally controlled, non-mechanical devices, in a matching network provides greater opportunity to fine tune control algorithms through programming.
EVCs exhibit superior low frequency (kHz) performance as compared to VVCs.

### Controlling RF Power for On-Wafer Process Improvement

As discussed above, each time a process is run on a semiconductor wafer, the conditions within the plasma chamber change slightly. This can be due, for example, to by-products of the process gases coating the plasma chamber walls, which may act like a small capacitor. These changes in the condition of the plasma chamber can cause wafer-to-wafer variation in the thickness of the deposited film. For example, increased coating of the chamber wall can cause the thickness of the deposited film to drop below an acceptable range.

The slight variations in the plasma impedance due to the changes in the plasma chamber condition can be measured by one or more sensors configured to detect a parameter related to the plasma chamber that is indicative of plasma impedance (e.g., voltage, current, phase, or impedance). This sensor may be in a variety of locations, including either externally or internally to the matching network. In one embodiment, the sensor is located at the input to the plasma chamber (or the output of the matching network), as is shown by sensor 49 of FIG. 2 and sensor 49 of FIG. 3.

As the matching network responds to the slight variations of the plasma chamber input impedance, there are resulting slight variations in the settings of the matching network's internal components, and slight variations in parameters associated with the matching network. Such internal components may be, for example, the one or more variable reactance elements of the matching network, such as (electronically or mechanically) variable capacitors or (electronically or mechanically) variable inductors.

In one embodiment of the disclosed system, the capacitor positions (or settings) of the variable capacitors of the matching network are monitored for multiple wafer runs and a correlation is determined between the film thickness and the capacitor position. This correlation may be determined for multiple processes and each relationship may be stored separately in one or more memory devices (e.g., the internal memory of the matching network). The film thickness may be determined, for example, by measuring the film thickness using one or more sensors. The capacitor position may be determined, for example, from data available to the control circuit that is controlling the one or more capacitors to enable an impedance match.

FIGS. 7 and 8 show example correlations between film thickness of a film deposited on a wafer (y-axis) and capacitor position (x-axis). FIG. 7's x-axis represents the capacitor position for a first variable capacitor (C1) of a matching network, while FIG. 8's x-axis represents the capacitor position for a second variable capacitor (C2) of the matching network. These two capacitors may be, for example, the variable capacitors 31, 33 of FIG. 2, or the variable capacitors 31A, 33A of FIG. 3, but the invention is not so limited (for example, the variable capacitors may be mechanically variable, the capacitors may be in an arrangement different from an L or pi topology, and there may be a different number of variable capacitors, such as only one).

In this example, the plots of FIGS. 1 and 2 are normalized with the starting capacitor position and film thickness (prior to the variations in plasma impedance caused by process gas by-products) normalized to 1, 1, though the invention does not require such normalization. For each graph, a trend line 71, 81 is provided for the relevant data points. As may be observed from these graphs, for each capacitor (C1 and C2), as film thickness increases (due to, for example, process gas by-products coating the plasma chamber walls), capacitor position decreases. The capacitor position may represent, for example, a percentage of the maximum capacitance the capacitor is capable of providing. For example, for the first capacitor (C1), normalized position 1 may correspond with 40% of the first variable capacitor's maximum capacitance, and normalized position 2 may correspond with 50% of the second variable capacitor's maximum capacitance. In this example, in FIG. 7, the capacitor position of 0.998 would correspond with (40%)*(0.998), or 39.92% of the first variable capacitor's maximum capacitance.

Once the correlations are stored in memory, the control circuit of the semiconductor device processing system (e.g., control circuit 45 discussed above) can monitor the capacitor position variation from the starting point (e.g., 1), and can use the capacitor position to determine a variations in the thickness of the deposited film.

Further, another correlation may exist in the system that ties the film thickness of the deposited film and the RF power fed by the RF source to the RF matching network. The second correlation data may be based on film thickness values and, for each film thickness value, a corresponding RF power setting for the RF source. For example, the second correlation data may indicate that a first power setting corresponds with a first film thickness, while a second power setting corresponds with a second film thickness.

The two correlations (capacitor position v. film thickness, and film thickness v. RF power) may be used to adjust the RF power such that the film thickness is again brought back with acceptable range. The RF source (e.g., RF source 15 of FIGS. 1-3) may adjust the amount of RF power going into the plasma chamber, for example, by increasing/decreasing the RF power, by increasing/decreasing the time the RF power is ON, or by increasing/decreasing the number of cycles the RF power turns ON/OFF.

It is noted that, while the above embodiment relied on capacitor position, this is just one example of a value that may associated with the matching network that may be used with the invention. Instead of a capacitor position, the invention may use any “matching network value,” where a matching network value may be understood as any value, position, or setting for a parameter associated with the matching network. For example, a matching network value may be a voltage (e.g., DC voltage) associated with the matching network, such as a voltage at the input 13 or output 17 of the matching network 11. In other embodiments, the matching network value may be a value for any voltage, current, phase, impedance, or harmonic (e.g., output V/I harmonics) associated with the matching network.

In view of the foregoing, referring to FIGS. 1-3, in one embodiment, the invention may be understood as a system 29 for adjustment of RF power delivered to a plasma chamber 19. The system 29 may adjust the RF power (e.g., increase the RF power) when the current deposited film thickness is below a desired film thickness range (due to, for example, by-products of process gases coating walls of the plasma chamber).

The system 29 includes a matching network 11 configured to be coupled between an RF source 15 and a plasma chamber 19. The system further includes one or more memory devices 46 configured to (a) store first correlation data, the first correlation data based on film thickness values and, for each film thickness value, a corresponding matching network value, wherein each matching network value is a value, position, or setting for a parameter associated with the matching network (discussed in further detail above); and (b) store second correlation data, the second correlation data based on film thickness values and, for each film thickness value, a corresponding RF power setting for the RF source. The correlation data may be based on sensor measurements from prior wafer runs, and may form part of one or more look up tables. The film thickness values of the first correlation data may be the same or overlapping with the film thickness values of the second correlation data. The first correlation data and/or the second correlation data may comprise a trend line (such as trend lines 71,81 of FIGS. 7-8), an equation, a function, or a machine learning algorithm representative of the relationship between (a) the film thickness values and the corresponding matching network values (e.g., FIGS. 7-8), and/or (b) the film thickness values and the corresponding RF power setting.

It is noted that the first and second correlation data may form part of a single collection of correlation data. The correlation data may be based on (a) film thickness values and, for each film thickness value, a corresponding matching network value, wherein each matching network value is a value for a parameter associated with the matching network; and (b) for each film thickness value, a corresponding RF power setting for the RF source. Further, the control circuit, rather than carrying out separate steps of determining the film thickness and then determining the power setting, may combine these steps. For example, the control circuit may be configured to: (a) for a current wafer run for a semiconductor wafer, determine a current matching network value for the parameter associated with the matching network; (b) using the current matching network value and the correlation data, determine the corresponding RF power setting for the RF source; and (c) transmit a control signal to the RF source to cause an adjustment of the RF power being output by the RF source based on the corresponding RF power setting to achieve a new film thickness for the semiconductor wafer of the current wafer run that is within a desired film thickness range.

The system 29 further includes a control circuit 45 (either part of the matching network or separate) operably coupled to the one or more memory devices 46. The control circuit 45 is configured to (a) for a current wafer run for a semiconductor wafer, determine a current matching network value for the parameter associated with the matching network; (b) using the current matching network value and the first correlation data, determine a current film thickness for the semiconductor wafer of the current wafer run; (c) using the current film thickness and the second correlation data, determine the corresponding RF power setting for the RF source; (d) transmit a control signal to the RF source to cause an adjustment of the RF power being output by the RF source based on the corresponding RF power setting to achieve a new film thickness for the semiconductor wafer of the current wafer run that is within a desired film thickness range.

In one embodiment, the corresponding RF power setting is a power setting sufficient to compensate for an undesired decrease in the film thickness value and bring the new film thickness within the desired film thickness range. In another embodiment, the corresponding RF power setting may comprise an adjustment value to a current RF power setting sufficient to bring the new film thickness within the desired film thickness range.

It is noted that the RF source and the matching circuit of the invention may be positioned in the same enclosure. Also, they may be in separate enclosures but in electrical communication (e.g., operably coupled to the same control circuit). Further, while a single control circuit may control both the matching circuit and the RF source, the invention is not so limited. In other embodiments, the control circuit may be comprised of more than one control circuit.

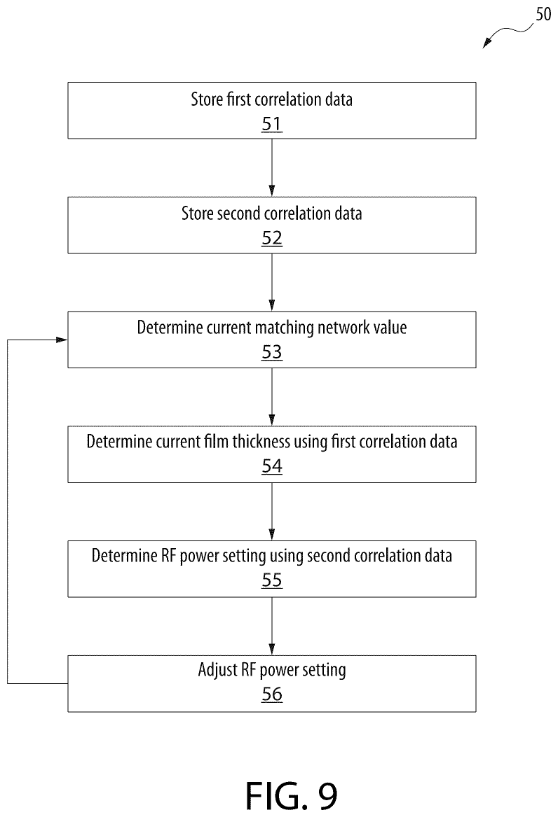

The invention may be, in another aspect, a method for adjustment of RF power delivered to a plasma chamber. FIG. 9 provides a flow chart of such a method. The method includes: (a) storing or accessing first correlation data, the first correlation data based on film thickness values and, for each film thickness value, a corresponding matching network value, wherein each matching network value is a value for a parameter associated with a matching network coupled between an RF source and a plasma chamber (operation 51); (b) storing or accessing second correlation data, the second correlation data based on film thickness values and, for each film thickness value, a corresponding RF power setting for the RF source (operation 52); (c) for a current wafer run for a semiconductor wafer, determining a current matching network value for the parameter associated with the matching network (operation 53); (d) using the current matching network value and the first correlation data, determining a current film thickness for the semiconductor wafer of the current wafer run (operation 54); (e) using the current film thickness and the second correlation data, determining the corresponding RF power setting for the RF source (operation 55); (f) causing adjustment of the RF power being output by the RF source based on the corresponding RF power setting to achieve a new film thickness for the semiconductor wafer of the current wafer run that is within a desired film thickness range (operation 56).

It is noted that, while the above discussion has focused on adjusting the power delivered to the plasma chamber (to prevent variations in film thickness) by adjusting the power being output by the RF source, the invention is not so limited. For example, the adjustment of the RF power being delivered to the plasma chamber may comprise adjusting a reactance of a variable reactance element (VRE) forming part of the matching network. For example, the VRE may be an variable capacitor (such as an EVC), and adjusting the variable capacitor may be a means of adjusting the RF power delivered to the plasma chamber. Such adjustment of a variable capacitor to prevent variations in film thickness is discussed in detail in U.S. Pat. No. 11,393,659, which is hereby incorporated by reference in its entirety (see, e.g., the section entitled Controlling Power to Plasma Chamber).

The method and system discussed herein provides several advantages. For example, by compensating for conditions in the plasma chamber, the plasma chamber requires less regular maintenance, thus increasing the uptime of the processing equipment and the general profitability of the system.

While the embodiments of a matching network discussed herein have used L or pi configurations, it is noted that he claimed matching network may be configured in other matching network configurations, such as a ‘T’ type configuration. Unless stated otherwise, the variable capacitors, switching circuits, and methods discussed herein may be used with any configuration appropriate for a matching network.

While the embodiments discussed herein use one or more variable capacitors in a matching network to achieve an impedance match, it is noted that any variable reactance element can be used. A variable reactance element can include one or more discrete reactance elements, where a reactance element is a capacitor or inductor or similar reactive device.

While the inventions have been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present inventions. Thus, the spirit and scope of the inventions should be construed broadly as set forth in the appended claims.

What is claimed is:

1. A system for adjustment of radio frequency (RF) power delivered to a plasma chamber, the system comprising:
a matching network configured to be coupled between an RF source and a plasma chamber;
one or more memory devices configured to:
store first correlation data, the first correlation data based on film thickness values and, for each film thickness value, a corresponding matching network value, wherein each matching network value is a value, position, or setting for a parameter associated with the matching network; and
store second correlation data, the second correlation data based on film thickness values and, for each film thickness value, a corresponding RF power setting for the RF source; and
a control circuit operably coupled to the one or more memory devices, the control circuit configured to:
for a current wafer run for a semiconductor wafer, determine a current matching network value for the parameter associated with the matching network;
using the current matching network value and the first correlation data, determine a current film thickness for the semiconductor wafer of the current wafer run;
using the current film thickness and the second correlation data, determine the corresponding RF power setting for the RF source; and
transmit a control signal to the RF source to cause an adjustment of the RF power being output by the RF source based on the corresponding RF power setting to achieve a new film thickness for the semiconductor wafer of the current wafer run that is within a desired film thickness range.

2. The system of claim 1 wherein the corresponding RF power setting comprises a setting or adjustment for the RF source or the matching network sufficient to cause the RF power delivered to the plasma chamber to compensate for an undesired decrease in the film thickness value and bring the new film thickness within the desired film thickness range.

3. The system of claim 2 wherein the decrease in the film thickness value is caused by byproducts of process gases coating walls of the plasma chamber.

4. The system of claim 1 wherein the first correlation data and the second correlation data are based on sensor measurements from prior wafer runs.

5. The system of claim 1 wherein the first correlation data forms part of a first lookup table, and the second correlation data forms part of a second lookup table.

6. The system of claim 1 wherein the film thickness values of the second correlation data are based on the film thickness values of the first correlation data.

7. The system of claim 1:
wherein the first correlation data comprises a trend line, an equation, a function, or a machine learning algorithm representative of a relationship between the film thickness values and the corresponding matching network values; or
wherein the second correlation data comprises a trend line, an equation, a function, or a machine learning algorithm representative of a relationship between the film thickness values and the corresponding RF power setting.

8. The system of claim 1 wherein the matching network value is a position of a variable reactance element (VRE) forming part of the matching network.

9. The system of claim 8 wherein the VRE is an electronically variable capacitor comprising a plurality of fixed capacitors coupled in parallel.

10. The system of claim 8 wherein the VRE is a mechanically variable capacitor and the matching network value is representative of a percentage of capacitance being provided by the mechanically variable capacitor.

11. The system of claim 1 wherein the matching network value is a DC voltage at an input or output of the matching network.

12. The system of claim 1 wherein the matching network value is a value for a voltage, current, impedance, or harmonic associated with the matching network.

13. A method for adjustment of RF power delivered to a plasma chamber, the method comprising:
storing or accessing first correlation data, the first correlation data based on film thickness values and, for each film thickness value, a corresponding matching network value, wherein each matching network value is a value for a parameter associated with a matching network coupled between an RF source and a plasma chamber;
storing or accessing second correlation data, the second correlation data based on film thickness values and, for each film thickness value, a corresponding RF power setting for the RF source;
for a current wafer run for a semiconductor wafer, determining a current matching network value for the parameter associated with the matching network;
using the current matching network value and the first correlation data, determining a current film thickness for the semiconductor wafer of the current wafer run;
using the current film thickness and the second correlation data, determining the corresponding RF power setting for the RF source; and
causing adjustment of the RF power being output by the RF source based on the corresponding RF power setting to achieve a new film thickness for the semiconductor wafer of the current wafer run that is within a desired film thickness range.

14. The method of claim 13 wherein the corresponding RF power setting comprises a setting or adjustment for the RF source or the matching network sufficient to cause the RF power delivered to the plasma chamber to compensate for an undesired decrease in the film thickness value and bring the new film thickness within the desired film thickness range.

15. The method of claim 14 wherein the decrease in the film thickness value is caused by byproducts of process gases coating walls of the plasma chamber.

16. The method of claim 13 wherein the first correlation data and the second correlation data are based on sensor measurements from prior wafer runs.

17. A system for adjustment of RF power delivered to a plasma chamber, the system comprising:
a matching network configured to be coupled between an RF source and a plasma chamber;
one or more memory devices configured to store correlation data based on:
film thickness values and, for each film thickness value, a corresponding matching network value, wherein each matching network value is a value for a parameter associated with the matching network; and
for each film thickness value, a corresponding RF power setting for the RF source; and
a control circuit operably coupled to the one or more memory devices, the control circuit configured to:
for a current wafer run for a semiconductor wafer, determine a current matching network value for the parameter associated with the matching network;
using the current matching network value and the correlation data, determine the corresponding RF power setting; and
transmit a control signal to cause an adjustment of an RF power being delivered to the plasma chamber based on the corresponding RF power setting to achieve a new film thickness for the semiconductor wafer of the current wafer run that is within a desired film thickness range.

18. The system of claim 17 wherein the corresponding RF power setting comprises a setting or adjustment for the RF source or the matching network sufficient to cause the RF power delivered to the plasma chamber to compensate for an undesired decrease in the film thickness value and bring the new film thickness within the desired film thickness range.

19. The system of claim 17 wherein the control signal is transmitted to the RF source, and the adjustment of the RF power being delivered to the plasma chamber comprises adjusting an RF power being output by the RF source.

20. The system of claim 17 wherein the control signal is transmitted to the matching network, and the adjustment of the RF power being delivered to the plasma chamber comprises adjusting a reactance of a variable reactance element (VRE) forming part of the matching network.
